(19) United States
(12) Patent Application Publication
(10) Pub. No.: US 2020/0294592 A1
(43) Pub. Date: Sep. 17, 2020

(54) DEVICE AND METHOD FOR BACKUP SIGNAL MANAGEMENT

(71) Applicant: HEWLETT PACKARD ENTERPRISE DEVELOPMENT LP, Houston, TX (US)

(72) Inventors: Michael R. Krause, Boulder Creek, CA (US); Melvin K. Benedict, Magnolia, TX (US)

(21) Appl. No.: 16/352,306

(22) Filed: Mar. 13, 2019

(51) Int. Cl. G11C 14/00; G06F 11/14; G11C 29/52; G06F 3/06; G11C 7/24; G11C 7/04

(52) U.S. Cl. CPC G11C 14/00; G06F 11/1458; G11C 29/52; G06F 3/0619; G11C 5/141; G06F 3/0685; G11C 7/24; G11C 7/04; G11C 2207/2227; G06F 3/065

(57) ABSTRACT

A device including a controller coupled to a primary medium including data provided by a processor, the controller configured to initiate an emergency backup for the primary medium, is provided. The device also includes a secondary medium coupled to the controller, and configured to store at least a portion of the data from the primary medium in the emergency backup. The device also includes an interface configured to provide to the controller, through a main power interface for the primary medium: an emergency backup signal to start the emergency backup, and a power to the primary medium during the emergency backup. A system including the device and a non-transitory medium with instructions to use the device in an emergency backup process are also provided.

### BACKGROUND

Systems for emergency backup of data stored in volatile memory in a processor tend to be bulky and cumbersome, typically requiring a separate and dedicated access to the printed circuit board housing the module where the volatile memory is located. Commonly used emergency backup systems use software involving complex routines to communicate with the volatile memory module, the processor, and the emergency power supply. This complexity prevents the application of a single emergency backup system for multiple volatile memory modules (e.g., in a multi-processor farm), where emergency data backup is critical. Accordingly, emergency data backup systems tend to occupy large space in a system, and to use multiple, expensive power sources.

### BRIEF DESCRIPTION OF THE DRAWINGS

The accompanying drawings, which are included to provide further understanding and are incorporated in and constitute a part of this specification, illustrate disclosed embodiments and together with the description serve to explain the principles of the disclosed embodiments. In the drawings:

FIG. 1A illustrates a circuit board including a controller, a primary medium, and a secondary medium for emergency backup storage in a system, according to certain aspects of the disclosure.

FIG. 1B illustrates an exemplary circuit board as in FIG. 1A, according to certain aspects of the disclosure.

FIG. 2A illustrates a circuit board as in FIG. 1A, further including a local power source for an emergency backup storage, according to some embodiments.

FIG. 2B illustrates a circuit board as in FIG. 1A, further including a local power source for an emergency backup storage, according to some embodiments.

FIG. 3A illustrates a system including multiple modules wherein a secondary medium is configured for emergency backup storage of at least one primary medium in a separate module, according to some embodiments.

FIG. 3B illustrates a system as in FIG. 3A, according to some embodiments.

FIG. 4 illustrates a system including multiple modules and a switch for emergency backup storage, according to some embodiments.

FIG. 5 is a flow chart illustrating steps in a method for performing an emergency backup of a primary medium into a secondary medium for storage, according to some embodiments.

In the figures, elements and steps denoted by the same or similar reference numerals are associated with the same or similar elements and steps, unless indicated otherwise.

### DETAILED DESCRIPTION

In the following detailed description, numerous specific details are set forth to provide a full understanding of the present disclosure. It will be apparent, however, to one ordinarily skilled in the art, that the embodiments of the present disclosure may be practiced without some of these specific details. In other instances, well-known structures and techniques have not been shown in detail so as not to obscure the disclosure.

The present disclosure is directed to emergency backup management of computer data stored in volatile memory. More specifically, the present disclosure is related to management interfaces for emergency data backup from one or more modules using a tethered power source or a local power source in each module. In embodiments consistent with the present disclosure, a tethered power source is configured to deliver power through a set of tethered power pins within the primary module connector or through an independent connector (e.g., a cabled power connector).

Embodiments as disclosed herein include a single-wire management interface to communicate to a controller status information about an emergency backup power source. The status information may include a presence, a readiness, error states, and the like. The single-wire management interface also communicates to the controller an emergency backup signal when the emergency backup is desirable (e.g., triggered). Accordingly, the single-wire management interface simplifies the hardware implementation of an emergency backup system as disclosed herein, further enabling the use of shared resources for the backup system by multiple primary media that may or may not be co-located in the same circuit board or a different circuit board. Moreover, in some embodiments, the primary media and the backup secondary media may or may not be in the same module.

In some embodiments, a tethered power source (TPS) provides emergency power through the main power interfaces of a module that supports the primary media holding the data that is backed up. Accordingly, in some embodiments, support for a separate cable/link to attach a TPS or to support a dedicated emergency backup power pin to the module is not necessary.

### General Overview

In one embodiment of the present disclosure a device as disclosed herein includes a controller coupled to a primary medium including data provided by a processor, the controller configured to initiate an emergency backup for the primary medium. The device also includes a secondary medium coupled to the controller, and configured to store at least a portion of the data from the primary medium in the emergency backup. The device also includes an interface configured to provide to the controller, through a main power interface for the primary medium: an emergency backup signal to start the emergency backup, and a power to the primary medium during the emergency backup.

According to one embodiment, a system includes a backup storage and a first module. The first module includes a controller, coupled to a primary medium including data provided by a processor, the controller configured to initiate an emergency backup for the primary medium, and to transfer at least a portion of the data from the primary medium to the backup storage in the emergency backup. The first module also includes a interface configured to provide to the controller, through a main power interface for the primary medium: an emergency backup signal to start the emergency backup, and a power to the primary medium during the emergency backup.

According to one embodiment, a non-transitory, computer readable medium includes instructions which, when executed by a processor, cause a device to perform a method, the method including issuing, to a controller in a circuit, an emergency backup signal comprising at least one of a power loss event, a volatile data loss event, a reset command, a status check command, or a temperature event, in the circuit. The method also includes verifying, using a single wire protocol, that a processor having write access to a primary medium in the circuit has written a modified data in the primary medium, asserting the emergency backup signal, and transferring at least a portion of the modified data from the primary medium to a secondary medium for emergency storage.

In yet other embodiment, a system is described that includes a means for storing commands and a means for executing the commands causing the system to perform a method that includes issuing, to a controller in a circuit, an emergency backup signal comprising at least one of a power loss event, a volatile data loss event, a reset command, a status check command, or a temperature event, in the circuit. The method also includes verifying, using a single wire protocol, that a processor having write access to a primary medium in the circuit has written a modified data in the primary medium, asserting the emergency backup signal, and transferring at least a portion of the modified data from the primary medium to a secondary medium for emergency storage.

It is understood that other configurations of the subject technology will become readily apparent to those skilled in the art from the following detailed description, wherein various configurations of the subject technology are shown and described by way of illustration. As will be realized, the subject technology is capable of other and different configurations and its several details are capable of modification in various other respects, all without departing from the scope of the subject technology. Accordingly, the drawings and detailed description are to be regarded as illustrative in nature and not as restrictive.

### Example System Architecture

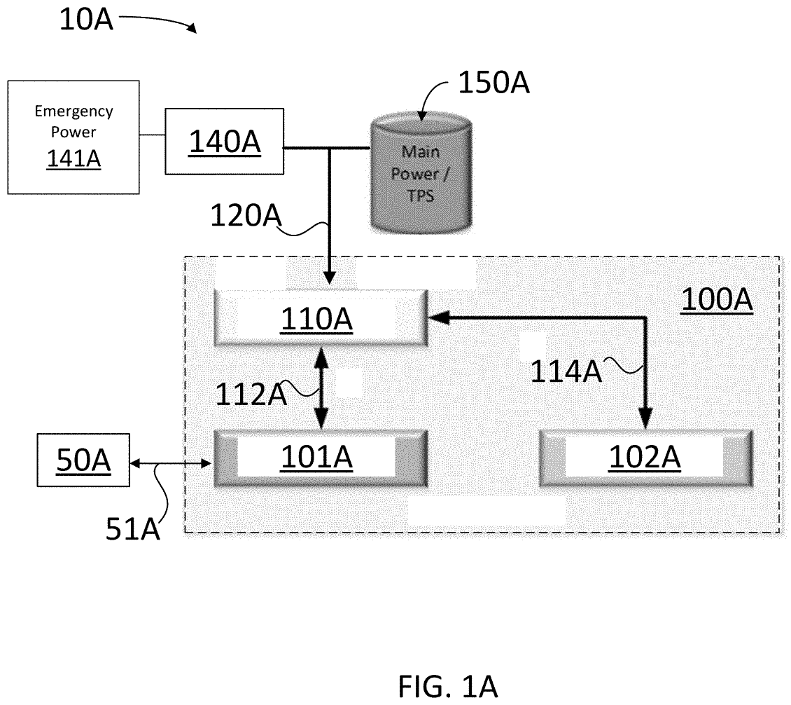

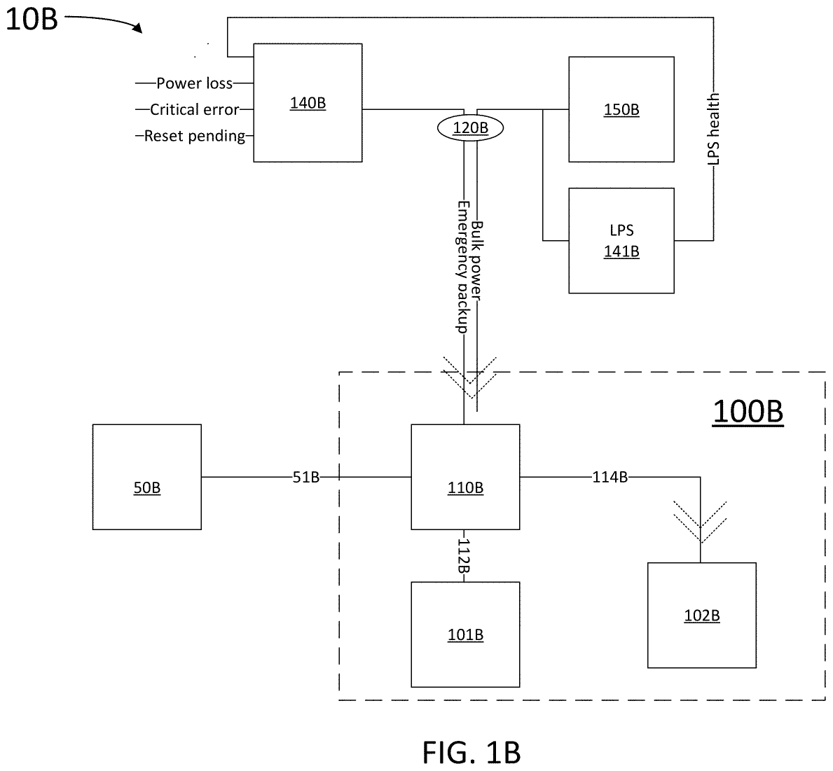

FIG. 1A illustrates a module 100A including a controller 110A, a primary medium 101A, and a secondary medium 102A for emergency backup storage in a system 10A, according to certain aspects of the disclosure. In embodiments as disclosed herein, a module includes a collection of components interactively cooperating according to embodiments as disclosed herein. For example, a dual in-line memory module (DIMM) is considered a module. More generally, a module is a physical package or mechanical form factor including one or more components interacting with each other. A module may, but not necessarily be, replaceable. In some embodiments, module 100A is part of a media module in a computer architecture 10A. Controller 110A is coupled to primary medium 101A through a link 112A, and to secondary medium 102A through a link 114A. In some embodiments, controller 110 is an application specific integrated circuit (ASIC). For example, the controller 110A may be a media controller for primary medium 101A. While the figure illustrates link 112A coupling controller 110A to primary medium 101A, there are a variety of ways to do so. For example, controller 110A can be attached using a 3D die stack where the logic is located at one end of the stack and the media above it. In some embodiments, controller 110A can be attached through a silicon interposer in a 2D topology to one or more media devices/die stacks. In some embodiments, controller 110A can be attached through FR4 like board material using copper traces to a variety of media devices (this is what a DIMM does) or can be incorporated with silicon photonics. In some embodiments, controller 110A can be attached using a 3D die stack where the logic is located at one end of the stack and the media above it. In some embodiments, controller 110A can be attached through a silicon interposer in a 2D topology to one or more media devices/die stacks. In some embodiments, controller 110A can be attached through Plexiglas or polycarbonate board material using copper traces to a variety of media devices (this is what a DIMM does) or can be attached using silicon photonics.

Primary medium 101A may be a cache memory or other volatile memory including data provided by a processor 50A through a memory interface 51A, e.g., random access memory (RAM) such as dynamic RAM (DRAM), nonvolatile RAM (NVRAM), static RAM (SRAM), and any combination thereof. In some embodiments, primary medium 101A includes an addressable register storing temporary data used by processor 50A. Controller 110A may be configured to initiate an emergency backup for primary medium 101A. In some embodiments, controller 110A may be configured to asynchronously flush a cache in processor 50A onto the primary medium once a main power to the circuit is lost, and before asserting the emergency backup signal. A secondary medium 102A may be coupled to controller 110A via a link 114A. In some embodiments, secondary medium 102A may be replaceable. Secondary medium 102A may include a non-volatile memory circuit, e.g., NVRAM such as phase change memory, memristor based memory, and flash back DRAM, solid state drives (SSD), flash memory, or even a magnetic hard drive, and combinations thereof. Secondary medium 102A is configured to store at least a portion of the data from primary medium 101A in the emergency backup. A main power interface 120A is configured to provide to the controller, through a main power interface for the primary medium: an emergency backup signal 140A to start the emergency backup, and a power to the primary medium during the emergency backup. Main power interface 120A may include a single wire providing power to medium 101A and carrying the emergency backup signal 140A. In some embodiments, to provide emergency backup signal 140A, main power interface 120A is configured to sense when a power source for primary medium 101A has been lost or becomes unstable. In that regard, main power interface 120A components such power sensors/logic can detect power loss and voltage regulators which condition the power can determine if power is unstable. When either of these detect an issue, they can assert a signal or transmit a packet to management logic that initiates the emergency backup logic. In that regard, an emergency power source such as a tethered power source (TPS) 150A is configured to provide an emergency power to primary medium 101A. In some embodiments, TPS 150A may include a main power supply co-packaged with a tethered emergency power source. The emergency power provided by TPS 150A is sufficient to last for at least as long as it would take for data in primary medium 101A to be transferred to secondary medium 102A. In some embodiments, the emergency power may be provided by a second emergency power source 141A. In some cases, emergency power is supplied for the entire platform from a single source as opposed to tethered emergency power on an individual module basis.

Emergency backup signal 140A is transmitted according to a single-wire protocol rather than as an assertion signal. In some embodiments, the single-wire protocol may include a series of pulse patterns to indicate the status of TPS 150A. In some embodiments, the failure of the back-up power source 141A or TPS portion of co-packaged power source 150A can trigger a back-up operation (sequence). Accordingly, when TPS 150A fails, primary medium 101A can be backed up using the main power and the applications migrated to a resilient configuration for data persistency. For example, when emergency backup signal 140A is successfully armed, a pulse duration of 10 micro-seconds (μs, 1 μs=10⁻⁶ seconds) could trigger emergency backup. Armed means that when emergency backup signal 140 is asserted, then a backup will be initiated. In some embodiments, it is desired to act upon a signal until all modules are in a valid state to avoid information loss or corrupted data. For other operations, some embodiments include a prefix, such as a predefined 64 cycle signal to each pulse sequence to enable the receiver (e.g., controller 110A) to detect that a request is forthcoming followed by the actual number of pulses that encode the operation or status information. In some embodiments, the pulse sequence acts as a warning of impending operation. For example, the pulse sequence may include a pattern (any pattern or voltage level) acting as a prelude for what is to follow. The prelude ensures that emitter and receiver of the pattern understand which is controlling the signal/link at the moment and when to interpret the data/pattern as a valid command. The commands may be commands to report TPS or LPS health/charging or to initiate an operation such as a backup or to arm the logic to interpret the emergency backup signal. In some cases this provided time to exit sleep or low power states. In some embodiments, the pulse patterns may be used to signal back to other components connected to the power lines that a backup operation is in progress. Other schemes (e.g., different durations for emergency backup signal 140A, and more or less than 64 cycle prelude to each pulse sequence) may be selected according to specific configurations and applications of the techniques disclosed herein.

The pulse patterns in the single-wire protocol may include a pre-selected number of voltage/current pulses, each having a pre-selected duration. Accordingly, controller 110 may count the pulses and determine the pulse duration, and compare the value with a look-up table, to determine the command or action associated with the pulse pattern. Further, in some embodiments, main power interface 120A includes a voltage divider to indicate a source of the single-wire to controller 110A (e.g., TPS 150A, or other source of emergency backup signal 140A). In some embodiments, it is desirable that controller 110A be able to detect where a power load may occur and the amount of load. This enables controller 110A to determine when a given configuration can be safely powered up, and when to shift resources elsewhere. Status and control information may be transferred on the single wire signal. Accordingly, the single-wire protocol obviates the need for software to configure the presence, status, and other parameters of TPS 150A. Thus, in some embodiments, software may assert the signal (not required). This simplifies management and implementation of an emergency backup in computer architecture 10A. Some embodiments may include multiple protocols for an emergency backup signal management. The protocols can communicate multiple types of information based on which side of the wire the logic exists. Some embodiments as disclosed herein may include a one-wire protocol proposing the voltage divider to indicate which side can transmit the protocol and proposing the protocol to be a series of pulse patterns. An enclosure-driven patterns protocol includes detecting that TPS 150A is present, that TPS 150A is not charged, or a failure of TPS 150A (e.g., not operational), that TPS 150A is removed or unplugged, that an alarm in TPS 150A indicates a need to be interrogated for change in status, e.g. used to signal EOL/pre-failure condition. The enclosure-driven pattern protocol may also include commands to initiate an emergency backup (a single 5 μs pulse), and to initiate an emergency power break (e.g., a single 10 μs pulse). A media module-driven pattern protocol includes TPS support commands, LPS support commands, an Emergency Backup Initiated command, an Emergency Backup Completed command, an Emergency Power Break Initiated command, and a TPS Status Check command. In some embodiments, the single-wire protocol through main power interface 120 may include enclosure-driven patterns for controller 110A such as: TPS Present, TPS Not Charged, TPS Charged, TPS Failure/Not Operational, TPS Removed/Unplugged, and TPS Alarm (e.g., desirability to interrogate TPS 150A for a change in status, e.g., used to signal EOL/pre-failure condition). Accordingly, controller 110A may trigger a back-up or set status indicating back-up is not possible.

Other examples of pulse patterns used in a single-wire protocol may include a single 5 μs pulse for initiating an emergency backup procedure. A pulse pattern may include a single 10 μs pulse that instructs controller 110A to initiate an emergency power break. An emergency power break is a compute signal indicating a critical power shortfall has been detected. Further, in some embodiments, the single-wire protocol through main power interface 120A may include module-driven patterns (e.g., from module 100A) such as: “Support Emergency Backup Signal,” “Emergency Backup Initiated,” “Emergency Backup Completed,” “Emergency Power Break Initiated,” and “Status Check of the TPS.” The above module-driven patterns are status signals that controller 110A uses to maintain a sufficient power supply to primary medium 101A.

In some embodiments, emergency backup signal 140A may also include an emergency power reduction signal through main power interface 120A. The emergency power reduction signal may include a power brake signal sharing the same pin as the emergency backup signal. This avoids adding another pin to main power interface 120A, when there are no spare pins in a common portion of the pinout applicable to multiple connector sizes of main power interface 120A. An emergency power reduction may be initiated by controller 110A upon receipt of the emergency power reduction signal. Due to the time-sensitive nature of environmental or safety conditions, some embodiments include a package-specific or mechanical form factor-specific, out-of-band emergency power reduction signal to inform controller 110A (this signal may be referred to as “PWRBRK#”). While this signal is asserted, TPS 150A is maintained below a maximum emergency power level.

In embodiments that support both, it is desirable that an emergency backup signal and an emergency power reduction signal be enabled at separate times. Emergency backup signal 140A is not necessarily linked to an “emergency.” More generally, emergency backup signal 140A may be triggered by software executed by processor 50A, based on non-power events, or could be triggered as part of a planned backup service scheduled in controller 110A.

An emergency backup operation with module 100A involves copying at least a portion of the addressable contents in primary medium 101A to secondary medium 102A. A module including primary medium 101A supports multiple resources and capabilities to perform emergency backup operations. These could include wear leveling of the secondary media, version (tine) control of multiple images, erasure of one or more images on the secondary media. For example, in some embodiments, secondary medium 102A is provisioned with memory resources that are equal to, or greater than, the memory resources of the primary medium 101A (including data integrity bits). In some embodiments, secondary medium 102A may be provisioned with memory resources capable of storing multiple versions of primary medium 101A.

In some embodiments, controller 110A is configured to identify emergency backup signal 140A from at least one of a power loss event, a volatile data loss event, a reset command, or a status check command, for the primary medium. In some embodiments, controller 110A distinguishes between emergency backup, software initiated backup and backup operation in progress. Without backup, operations such as reset—reboot, initialization of computer would typically loose volatile data. Accordingly, embodiments as disclosed herein save volatile data and reduce reboot time. In some embodiments, a status check command is desirable when the power cycle (failure duration) is indeterminate and resets and reboot processes at a rapid pace, compared to backup operation times, the platform must know when an operation is in progress to avoid interference.

An emergency backup power source (e.g. TPS 150A) may be configured to provide power to the primary medium 101A during the emergency backup. Controller 110A is configured to receive a presence and status information for emergency backup power source 150 from main power interface 120A. The presence and status information of backup power source 150A includes multiple commands to controller 110A such as a backup trigger of initialization, or logical assertion, to manage the emergency backup before emergency backup signal 140A is asserted. In some embodiments, TPS 150A may be charged up to a pre-selected value to serve as an emergency power source.

In some embodiments, controller 110A is configured to transfer data from a cache in processor 50A to primary medium 101A. Further, controller 110A may transfer the data from primary medium 101A to secondary medium 102A. Typically, this is a memory/processor function, however in the context of SCM or fabric attached storage, this is a new operational characteristic.

FIG. 1B illustrates an exemplary circuit board in a system 10B, according to certain aspects of the disclosure. System 10B may include similar components as described above in relation to system 10A. In system 10B, emergency backup signal 140B may be provided by a computer control logic, and the emergency power source 141B may include a local power source (LPS) communicatively coupled to the computer that provides emergency backup signal 140B. The computer checks the LPS health constantly (or at any pre-selected frequency), to ensure that LPS 141B is ready to provide the emergency power. An LPS may be a battery, capacitor, etc. that is located within or on a module. In some embodiments, LPS 141B provides power during an emergency backup. Module 100B monitors the health of LPS 141B and ensures that there is sufficient energy to support the specified operation. Module 100B may also support TPS 150B. In some embodiments, TPS 150B delivers power to module 100B through the module's connector primary power pins 120B. TPS 150B may be shared by multiple modules, and not just by module 100B (as is the case of LPS 141B). In system 10B, the computer logic may check for events such as a power loss, a critical error, or a reset pending, for triggering emergency backup signal 140B. The events are logically ordered so that when the backup complete the initiating event will be completed.

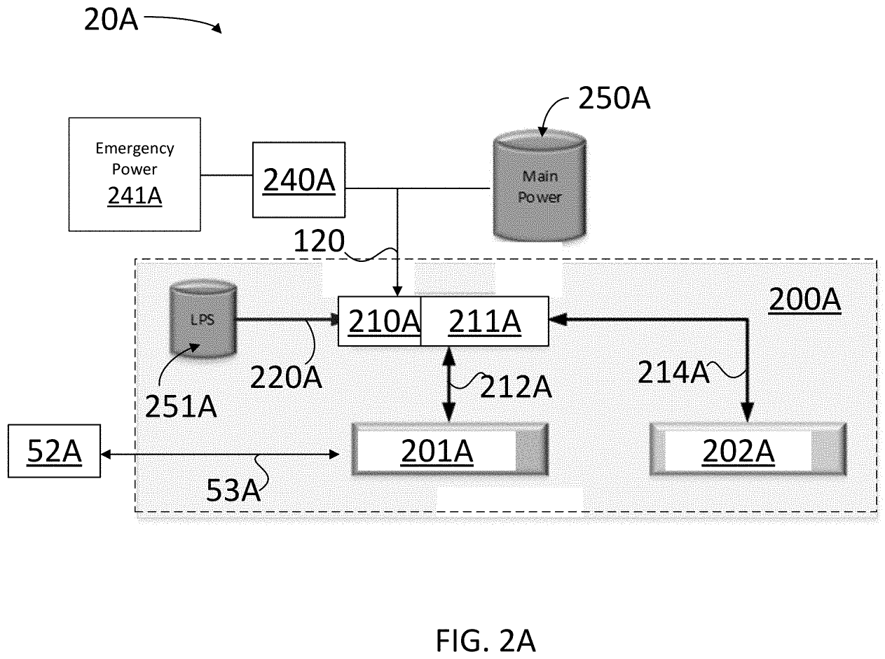

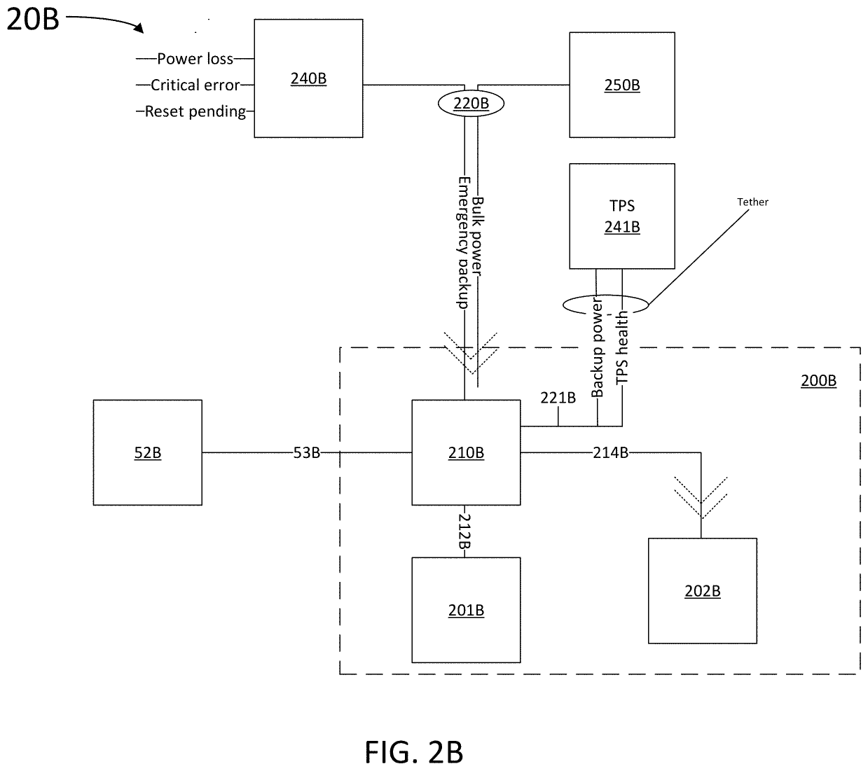

FIG. 2A illustrates a module 200A, further including a local power source (LPS) 250A for an emergency backup storage in a system 20A, according to some embodiments. In some embodiments, module 200A is part of a media module in a computer architecture 20A. LPS 250A may include a battery, a capacitor, and the like, and be located within or on a module. In some embodiments, controller 211A monitors a status of LPS 250A and notifies a system manager 52A (e.g., a baseboard management controller) of any issues through a single-wire protocol in an interface 220A. TPS 250A, processor 52A and a memory interface 53A in computer architecture 20A may be as described above (cf. computer architectures 10A and 10B). Further, links 212A and 214A in module 200A may be as described above (cf. modules 100A and 100B).

In some embodiments, module 200A includes a relay switch 210A coupling local power source 250A to main power interface 220A. In some embodiments, relay switch 210 may be a steering diode. In some embodiments, controller 210A activates relay switch 211A upon assertion of emergency backup signal 240A. In some embodiments, relay switch 210 includes a steering diode circuit to couple LPS 251A to main power interface 120 upon assertion of emergency backup signal 240A. In some embodiments, LPS 251A is a discrete power source such as a mechanical module that contains battery/capacitor storage. Accordingly, LPS 251A may be switched into operation when main power is lost. In some embodiments, LPS 251A is local to the enclosure in module 200A and could be driven from the rack level, external to module 200A.

In some embodiments, primary medium 201A and secondary medium 202A are co-located within a same mechanical module 200A and controller 210A may support the following operations on primary medium 201A: Backup, Restore, Erase, ARM, ARM and Erase, and Factory Default. Further, a single-wire protocol for module 200A may include a pulse pattern to controller 210A requesting for support on LPS 251A, as described above.

FIG. 2B illustrates a circuit board in a system 20B including a module 200B, according to some embodiments. System 20B may include similar components as described above in relation to system 20A. In system 20B, an emergency power source may include a tethered power source (TPS) communicatively coupled to an interface 221B in module 200B. Interface 221B checks the health and status of TPS 241B, to ensure that it is ready to provide emergency power when emergency backup signal 240B is asserted. In system 20B, the computer logic may check for events such as a power loss, a critical error, or a reset pending, for triggering emergency backup signal 240B.

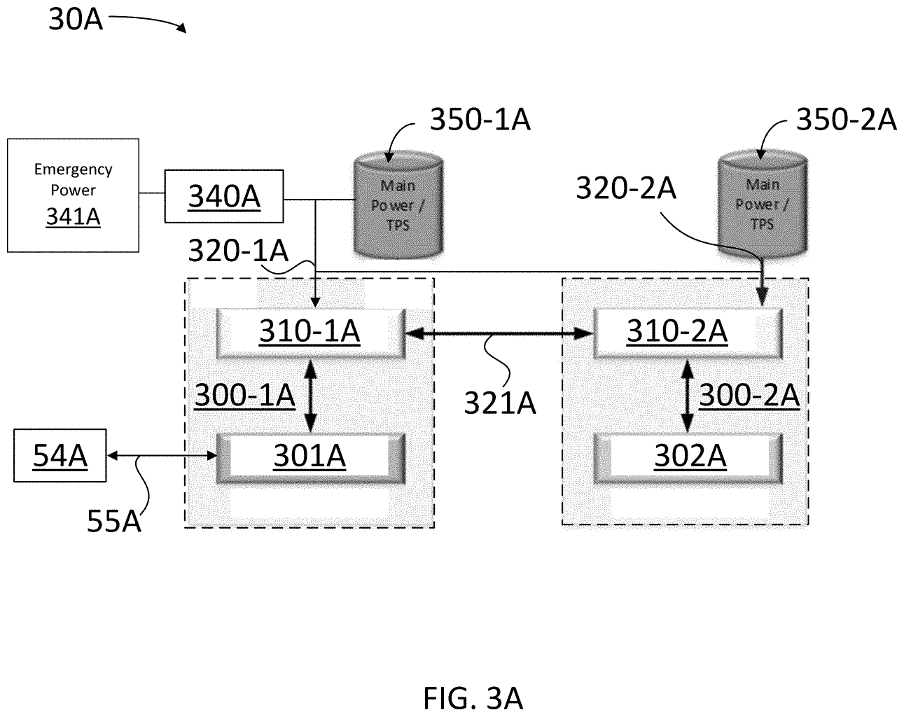

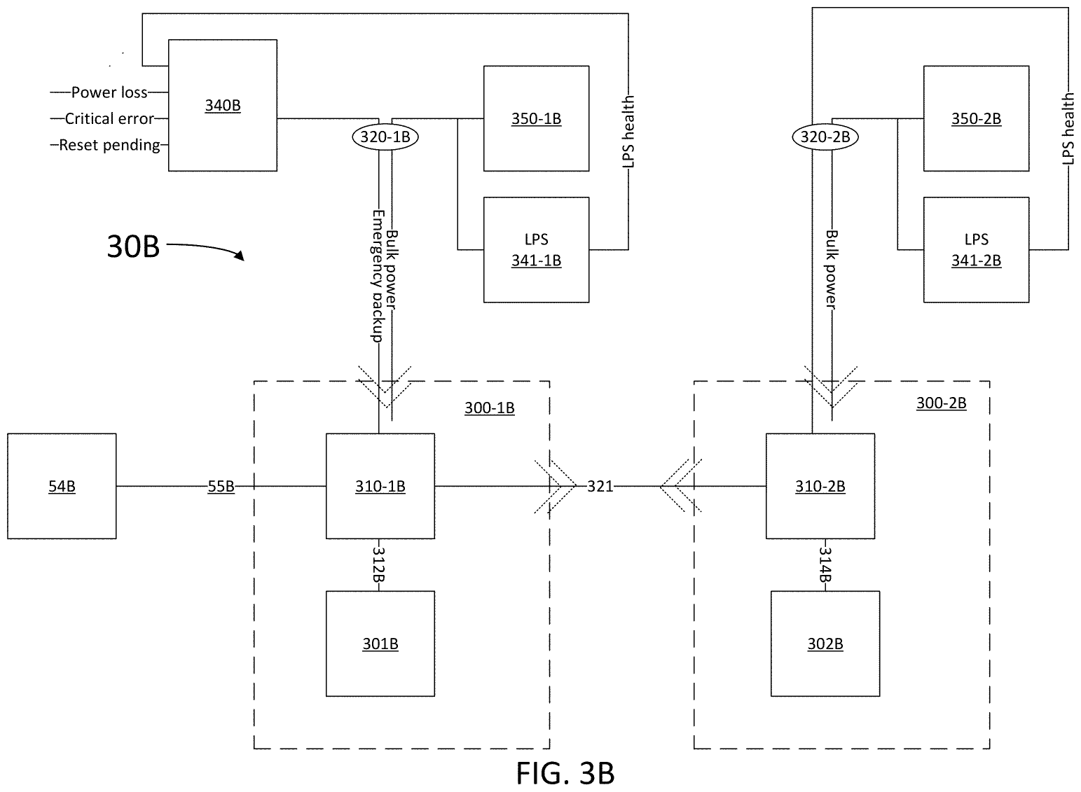

FIG. 3A illustrates a system 30A, including multiple modules wherein a secondary medium is configured for emergency backup storage of at least one primary medium in a separate module, according to some embodiments. System 30A includes a first module 300-1A having a primary medium 301A and a second module 300-2A having a secondary medium 302A (hereinafter, collectively referred to as “modules 300A”). System 30A may include a processor 54A and a memory interface 55A performing operations and providing data to primary medium 301A. In some embodiments, a link 321A enables a direct data transfer between modules 300A upon receipt, at controller 310-1A, of emergency backup signal 340A. For example, in some embodiments, link 321A may be configured in a point-to-point (P2P) topology and use the P2P protocols to exchange data. Emergency backup signal 140 and TPS 350-1A may be coupled to controller 310-1A through a single-wire protocol via interface 320-1A, as discussed above (e.g., main power interface 320A).

In some embodiments, first module 300-1A is configured in a point-to-point communication 321A with second module 300-2A. Each one of modules 300A may use a separate TPS 350-1A and 350-2A (hereinafter, collectively referred to as “TPSs 350A”), respectively. In some embodiments, two or more modules 300A may share a single TPS. Further, in some embodiments, multiple modules 300A share a single TPS 350A. Accordingly, each of modules 300 may be configured to separately monitor the status of TPSs 350A through interface 320-1A or an interface 320-2A (hereinafter, collectively referred to as “interfaces 320A”). Accordingly, in module 300-1A, controller 310-1A may be configured to monitor the status of TPS 350-1A. Likewise, in module 300-2A, controller 310-2A may be configured to monitor the status of TPS 350-2A. In some embodiments, TPS 350-1A and 350-2A are combined as a single entity to respond as a single entity. Accordingly, in some embodiments the status of TPS 350A is conveyed by signal 340A for appropriate system management. In embodiments consistent with the present disclosure, TPS 350A responds as a single entity, and backup determination is determined by emergency backup signal 340A through 310-1A. In some embodiments, the emergency power may be provided by an emergency power source 341A.

In some embodiments, to reduce cost, a shared TPS 350A may be desirable (e.g., a LPS may be costly and difficult to install in modules 300A). In some embodiments, shared TPS 350A may include an uninterruptible power supply (UPS) provisioned within one of modules 300A, or in a separate enclosure to provide emergency backup power through the main power interfaces of one or more modules 300A for one or more modules 300A in the event of main power loss or instability main power interface. In embodiments where module 300-1A is not co-located with module 300-2A, then controller 310-1A in module 300-1A may support the following operations: Backup, Restore, ARM, and Factory Default operations on primary medium 301A. More generally, the above listed operations are location-independent. Likewise, controller 310-2A in module 300-2A may support Erase and Factory Default operations on secondary medium 302A.

FIG. 3B illustrates a system 30B, according to some embodiments. System 30B may include similar components as described above in relation to system 30A. In system 30B, a computer logic may check for events such as a power loss, a critical error, or a reset pending, for triggering emergency backup signal 340B. In addition, the computer logic may use LPS 341-1B as an emergency power source, and continuously monitor for the health of LPS 341-1B. In some embodiments, main power source 350-2B may also be complemented by a second emergency power source 341-2B. In some embodiments, the health and status of LPS 341-2B may be monitored from module 300-2B.

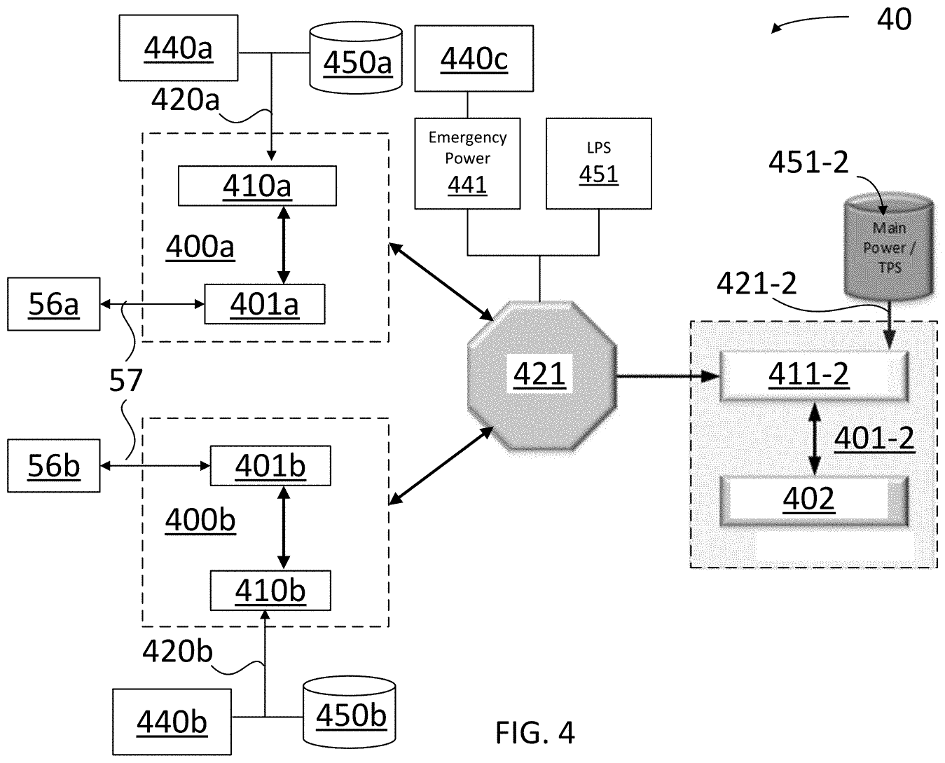

FIG. 4 illustrates a system 40 including multiple modules 400a and 400b (hereinafter, collectively referred to as “primary modules 400”) and 401-2, and a switch 421 for emergency backup storage, according to some embodiments. Switch 421 couples a first module 400a (including primary medium 401a) or a second module 400b (including primary medium 401b) to module 401-2 (including secondary medium 402) for emergency backup storage, according to some embodiments. Primary medium 401a includes data provided by a first processor 56a, and primary medium 401b includes data provided by a second processor 56b through storage interfaces 57. In general, modules 400a and 400b may be separated from one another and first processor 56a and second processor 56b may be independent. Further, each one of modules 400 in system 40 may include an emergency backup signal 440a and 440b (hereinafter, collectively referred to as “emergency backup signals 440”), and a backup power source 450a and 450b (hereinafter, collectively referred to as “power sources 450”), respectively. TPS 451-2 may provide power to secondary medium 402 and other components (e.g., controller 411-2) in module 401-2. Further, in embodiments as disclosed herein, controller 411-2 may monitor the status and condition of TPS 451-2 through interface 421-2. In addition to individual power sources 450, system 40 may include a common emergency power source 441 and an LPS 451 that provide emergency power to either one, or both, of modules 400 when a power loss event occurs (through switch 421).

In some embodiments, one or more of modules 400 may share the same emergency backup signal 440c. In such configurations, each of controllers 410 may be configured to adjust the semantics and logic to power up and transfer data from each of primary media 401 upon receipt of the common emergency backup signal 440c.

Each of primary modules 400 includes an interface 420a and 420b (hereinafter, collectively referred to as “interfaces 420”), and a controller 410a and 410b (hereinafter, collectively referred to as “controllers 410”), respectively. Upon receipt of any one of emergency backup signals 440, switch 421 selects one of modules 400 to start an emergency backup for one of primary media 401. Accordingly, switch 421 transfers at least a portion of data to secondary medium 402, for storage backup.

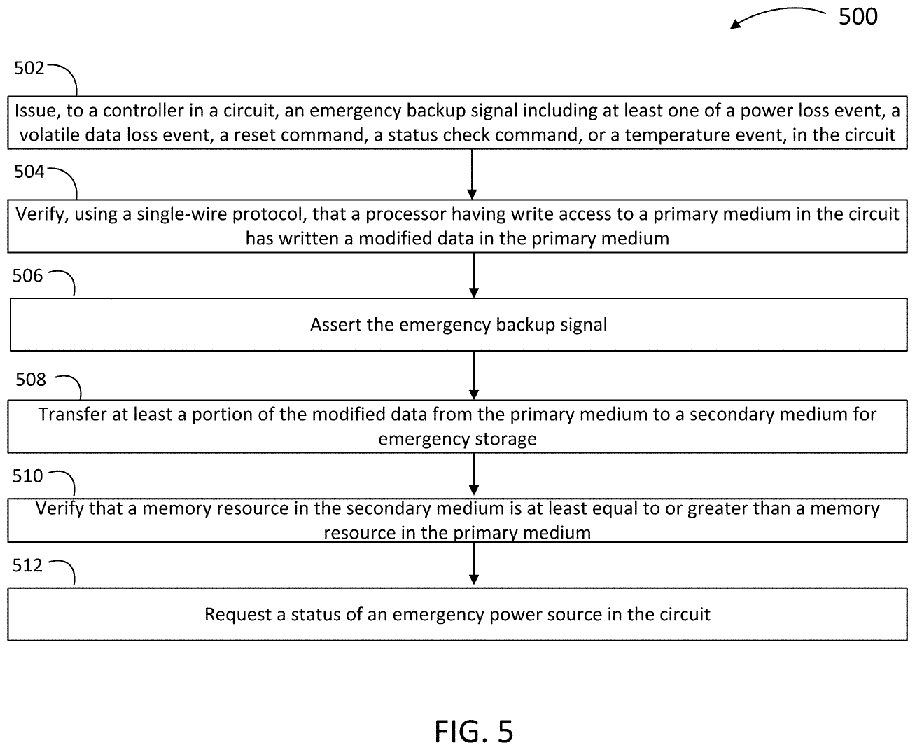

FIG. 5 is a flow chart illustrating steps in a method 500 for controlling a circuit board that supports an emergency backup for data in a primary media, according to some embodiments. Steps in method 500 may be performed by a controller of the primary medium that receives data from a processor in a computer architecture (e.g., controllers 110, processor 50, and computer architecture 10). The controller may transfer data from the primary medium to the secondary medium upon receipt of an emergency backup signal via a single-wire interface (e.g., emergency backup signal 140, main power interface 120). The controller and the primary medium may be included in a module having a local power source for emergency backup (e.g., LPS 250). In some embodiments, a tethered power source may be coupled to the module via a single wire interface to the controller (e.g., TPS 150, main power interface 120). The controller may communicate with the tethered power source via a single-wire protocol, and determine the status and capabilities of the tethered power source before an emergency backup event occurs. Methods consistent with the present disclosure may include at least one, but not all, of the steps in method 500. Further, methods consistent with the present disclosure may include one or more of the steps in method 500 performed in a different order, or performed overlapping in time, or almost simultaneously.

Step 502 includes issuing, to a controller in a circuit, an emergency backup signal including at least one of a power loss event, a volatile data loss event, a reset command, a status check command, or a temperature event. In some embodiments, step 502 may be initiated by a system management for the computer or module that includes the primary media. Due to the time-sensitive nature of an emergency backup, e.g., in case of a system failure, in some embodiments, step 502 includes providing a package-specific or mechanical form factor-specific out-of-band emergency backup signal to inform the controller to initiate an emergency backup. For example, in some embodiments an external out of band signal over fabric management message may include a package specific signal such as a PCIe “emergency brake” signal.

Step 504 includes verifying, using a single-wire protocol, that a processor having write access to a primary medium in the circuit has written a modified data in the primary medium. In some embodiments, step 504 includes ignoring the emergency backup signal when the system is performing a routine primary media backup, or a restore operation in the system.

Step 506 includes asserting the emergency backup signal. In some embodiments, step 506 includes overriding all other power management mechanisms except for power down and Power Disable (if supported by the module). In some embodiments, step 506 includes applying an emergency backup power to the entire module in the circuit board, including the primary media, the controller, and other components (e.g., the secondary media, when the secondary media is included in the circuit board). In some embodiments, step 506 includes verifying (e.g., prior to asserting the emergency backup signal) that at least one processor with write access to the primary media has written all modified data to the primary media (e.g., in the case of a processor cache that may not have been cleaned up or transferred to the primary media, before asserting the emergency backup signal). In some embodiments, step 506 may include triggering an emergency backup procedure when the emergency backup signal is asserted for the first time after a pre-selected time window or event (e.g., after a system boot, re-boot, or re-start).

Step 508 includes transferring at least a portion of the modified data from the primary medium to the secondary medium for emergency storage. In some embodiments, step 508 may be initiated within about two micro-seconds (2 μs), or even less, after the signal is asserted in step 506.

Step 510 includes verifying that a memory resource in the secondary medium is at least equal to or greater than a memory resource in the primary medium.

Step 512 includes requesting a status of an emergency power source in the circuit. In some embodiments, step 512 includes verifying a status of an emergency power source coupled to the circuit, and providing power from the emergency power source to the primary medium when the emergency backup signal includes a power loss event. In some embodiments, step 512 includes identifying a power emergency of a second primary medium including data from a second processor in a second circuit, and providing power from an emergency power source to the second primary medium. In some embodiments, step 512 includes providing power from an emergency power source to the primary medium by discharging a capacitor in the circuit onto a primary power pin coupled to the primary medium. In some embodiments, step 512 includes flushing a cache in the processor asynchronously onto the primary medium once a main power to the circuit is lost but before asserting the emergency backup signal, and transferring the at least one portion of the modified data after a cache in the processor has been transferred to the primary medium.

The term “machine-readable storage medium” or “computer readable medium” as used herein refers to any medium or media that participates in providing instructions to processor 502 for execution. Such a medium may take many forms, including, but not limited to, non-volatile media, volatile media, and transmission media. Non-volatile media include, for example, optical or magnetic disks, such as data storage 506. Volatile media include dynamic memory, such as memory 504. Transmission media include coaxial cables, copper wire, and fiber optics, including the wires forming bus 508. Common forms of machine-readable media include, for example, floppy disk, a flexible disk, hard disk, magnetic tape, any other magnetic medium, a CD-ROM, DVD, any other optical medium, a RAM, a PROM, an EPROM, a FLASH EPROM, any other memory chip or cartridge, or any other medium from which a computer can read. The machine-readable storage medium can be a machine-readable storage device, a machine-readable storage substrate, a memory device, a composition of matter affecting a machine-readable propagated signal, or a combination of one or more of them.

To illustrate the interchangeability of hardware and software, items such as the various illustrative blocks, modules, components, methods, operations, instructions, and algorithms have been described generally in terms of their functionality. Whether such functionality is implemented as hardware, software, or a combination of hardware and software depends upon the particular application and design constraints imposed on the overall system. Skilled artisans may implement the described functionality in varying ways for each particular application.

As used herein, the phrase “at least one of” preceding a series of items, with the terms “and” or “or” to separate any of the items, modifies the list as a whole, rather than each member of the list (i.e., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

To the extent that the term “include,” “have,” or the like is used in the description or the claims, such term is intended to be inclusive in a manner similar to the term “comprise” as “comprise” is interpreted when employed as a transitional word in a claim. The word “exemplary” is used herein to mean “serving as an example, instance, or illustration.” Any embodiment described herein as “exemplary” is not necessarily to be construed as preferred or advantageous over other embodiments.

A reference to an element in the singular is not intended to mean “one and only one” unless specifically stated, but rather “one or more.” Nothing disclosed herein is intended to be dedicated to the public regardless of whether such disclosure is explicitly recited in the above description. No clause element is to be construed under the provisions of 35 U.S.C. § 112, sixth paragraph, unless the element is expressly recited using the phrase “means for” or, in the case of a method clause, the element is recited using the phrase “step for.”

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can, in some cases, be excised from the combination, and the claimed combination may be directed to a subcombination or variation of a subcombination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products. Other variations are within the scope of the following claims.

Multiple variations and modifications are possible and consistent with embodiments disclosed herein. Although certain illustrative embodiments have been shown and described here, a wide range of modifications, changes, and substitutions is contemplated in the foregoing disclosure. While the above description contains many specifics, these should not be construed as limitations on the scope of the embodiment, but rather as exemplifications of one or another preferred embodiment thereof. In some instances, some features of the present embodiment may be employed without a corresponding use of the other features. Accordingly, it is appropriate that the foregoing description be construed broadly and understood as being given by way of illustration and example only, the spirit and scope of the embodiment being limited only by the appended claims.

What is claimed is:

1. A device, comprising:
a controller coupled to a primary medium including data provided by a processor, the controller configured to initiate an emergency backup for the primary medium;
a secondary medium coupled to the controller, and configured to store at least a portion of the data from the primary medium in the emergency backup; and
a main power interface for the primary medium, the main power interface configured to provide to the controller:
an emergency backup signal to start the emergency backup,
power to the primary medium during the emergency backup, and
power to secondary medium during the emergency backup.

2. The device of claim 1, wherein the controller is configured to identify the emergency backup signal from at least one of a power loss event, a volatile data loss event, a reset command, status check command, a software-based command, or a pre-scheduled backup service, for the primary medium.

3. The device of claim 1, further comprising an emergency backup power source configured to provide the power to the primary medium during the emergency backup, and wherein the controller is configured to receive a presence and status information for the emergency backup power source from the interface, further wherein the presence and status information comprises multiple commands to the controller to manage the emergency backup before the emergency backup signal is asserted.

4. The device of claim 1, wherein the primary medium comprises a volatile memory including a cache for the processor, and the secondary medium comprises a non-volatile memory.

5. The device of claim 1, further comprising a first module that includes the primary medium and a second module that includes the secondary medium configured in a point to point communication with the first module.

6. The device of claim 1, further comprising a second primary medium including a second data processed by a second processor, and wherein the emergency backup signal comprises a signal to start an emergency backup for the second primary medium, and wherein the interface is further configured to, upon receipt of the signal to start an emergency backup for the second primary medium, transfer at least a portion of the second data to the secondary medium.

7. The device of claim 1, further comprising a relay switch coupling an emergency backup power source to the interface, the relay switch configured to be activated by the controller upon assertion of the emergency backup signal.

8. The device of claim 1, further comprising a steering diode circuit to couple an emergency backup power source to the interface upon assertion of the emergency backup signal.

9. The device of claim 1, further comprising a tethered power supply that is charged up to a pre-selected value to serve as an emergency power source upon assertion of the emergency backup signal.

10. The device of claim 1, wherein the controller is configured to transfer data from a cache in the processor to the primary medium and from the primary medium to the secondary medium.

11. A system, comprising:
a backup storage; and
a first module, comprising:
a controller, coupled to a primary medium including data provided by a processor, the controller configured to initiate an emergency backup for the primary medium, and to transfer at least a portion of the data from the primary medium to the backup storage in the emergency backup; and
a main power interface for the primary medium, the main power interface configured to provide to the controller an emergency backup signal to start the emergency backup, and

12. The system of claim 11, wherein the controller is configured to identify the emergency backup signal from at least one of a power loss event, a volatile data loss event, a reset command, or a status check command, for the primary medium.

13. The system of claim 11, further comprising a power source configured to provide the power to the primary and secondary medium during the emergency backup, and wherein the interface is further configured to provide to the controller a presence and a status information for the power source.

14. The system of claim 11, further comprising a power source configured to provide the power to the primary and secondary medium during the emergency backup, wherein the power source comprises at least one of:
a remote power source tethered to the controller via a power cable; and
a local power source coupled to the main power interface of the primary medium.

15. The system of claim 11, further comprising a second module configured to support the backup storage and a second controller, the system further comprising a switch configured to transfer control of the emergency backup to the second controller upon receipt of the emergency backup signal.

16. The system of claim 11, further comprising a second module having a second primary medium including a second data processed by a second processor, and wherein the emergency backup signal comprises a signal to start an emergency backup for the second primary medium, and wherein the interface is further configured to start an emergency backup for the second primary medium.

17. A computer-implemented method, comprising:
issuing, to a controller in a circuit, an emergency backup signal comprising at least one of a power loss event, a volatile data loss event, a reset command, a status check command, or a temperature event, in the circuit;
verifying, using a single wire protocol, that a processor having write access to a primary medium in the circuit has written a modified data in the primary medium;
asserting the emergency backup signal; and
transferring at least a portion of the modified data from the primary medium to a secondary medium for emergency storage.

18. The computer-implemented method of claim 17, further comprising verifying a status of an emergency power source coupled to the circuit, and providing a power from the emergency power source to the primary medium when the emergency backup signal includes a power loss event.

19. The computer-implemented method of claim 17, further comprising identifying a power emergency of a second primary medium including data from a second processor in a second circuit, and providing power from an emergency power source to the second primary medium.

20. The computer-implemented method of claim 17, further comprising:
flushing a cache in the processor asynchronously onto the primary medium once a main power to the circuit is lost but before asserting the emergency backup signal; and
transferring the at least a portion of the modified data after a cache in the processor has been transferred to the primary medium.
